(19) United States
(12) Patent Application Publication
(10) Pub. No.: US 2025/0374834 A1
(43) Pub. Date: Dec. 4, 2025

(54) SEMICONDUCTOR INTEGRATED CIRCUIT DEVICE AND MANUFACTURING METHOD THEREFOR

(71) Applicant: XIAMEN INDUSTRIAL TECHNOLOGY RESEARCH INSTITUTE CO., LTD., Xiamen (CN)

(72) Inventors: Taiwei CHIU, Xiamen (CN); Wuxin LI, Xiamen (CN); Tingying SHEN, Xiamen (CN)

(73) Assignee: XIAMEN INDUSTRIAL TECHNOLOGY RESEARCH INSTITUTE CO., LTD., Xiamen (CN)

(21) Appl. No.: 18/874,091

(22) PCT Filed: May 31, 2023
(86) PCT No.: PCT/CN2023/097320

§ 371 Date: Dec. 12, 2024

(30) Foreign Application Priority Data
Sep. 27, 2022 (CN) 202211185161.3

(51) Int. Cl. H10N 70/20; H10B 63/00; H10N 70/00

(52) U.S. Cl. CPC H10N 70/20; H10N 70/021; H10B 63/00

(57) ABSTRACT

A semiconductor integrated circuit device and a manufacturing method therefor are provided. The semiconductor integrated circuit device includes a resistance layer, a first electrode and a second electrode which are respectively disposed at two sides of the resistance layer. The resistance layer is a layer of thin film covering a protruding block, the first electrode is either a part of the protruding block or is connected with a lower end of the protruding block, the second electrode is disposed above the resistance layer, and forms full coverage for the resistance layer, and the first electrode and the second electrode are enabled to form a conductive filament on a side wall of the resistance layer in a manner of arranging a first insulation layer above the first electrode. The resistance layer covers the protruding block, and the conductive filament is formed on the side wall of the resistance layer.

### CROSS REFERENCE TO THE RELATED APPLICATIONS

This application is the national phase entry of International Application No. PCT/CN2023/097320, filed on May 31, 2023, which is based upon and claims priority to Chinese Patent Application No. 202211185161.3, filed on Sep. 27, 2022, the entire contents of which are incorporated herein by reference.

### TECHNICAL FIELD

The present application relates to the field of semiconductor devices, and in particular to a semiconductor integrated circuit device and a manufacturing method therefor.

### BACKGROUND

A basic structure of a resistance random access memory (RRAM) includes a top electrode, a resistance layer (also called resistive switching layer), and a bottom electrode, where a sandwich structure stacked layer by layer from bottom to top is usually used, a size of a resistance region (also called resistive switching region) usually depends on a planar area of the RRAM, and currently, a demand for semiconductor devices tends towards miniaturization, so that the planar area of the RRAM is increasingly smaller.

The inventor of the present application found through experimental research that: the smaller the resistance region, the greater a forming voltage (FV) of a conductive filament and a plasma induced damage (PID) effect, so that poorer performance and shorter life of the semiconductor integrated circuit device are caused.

### SUMMARY

With regard to the above technical problems, the present applicant creatively provides a semiconductor integrated circuit device and a manufacturing method therefor.

According to a first aspect of the embodiments of the present application, a semiconductor integrated circuit device is provided, which includes: a resistance layer, a first electrode and a second electrode which are respectively disposed at two sides of the resistance layer; the resistance layer is a layer of thin film covering a protruding block, and includes a top with a first height, a bottom with a second height, and a side wall connecting the top with the bottom, and the second height is smaller than the first height; the first electrode is a part of the protruding block or is connected with a lower end of the protruding block; the second electrode is disposed above the resistance layer, and forms full coverage for the resistance layer; and the semiconductor integrated circuit device further includes a first insulation layer, and the first insulation layer is disposed above the first electrode, so that the first electrode and the second electrode form a conductive filament on the side wall of the resistance layer.

According to an embodiment of the present application, the semiconductor integrated circuit device may further include: an oxygen getting layer disposed between the first electrode and the resistance layer, or disposed between the second electrode and the resistance layer.

According to an embodiment of the present application, the semiconductor integrated circuit device may further include: an oxygen blocking layer disposed between the first insulation layer and the oxygen getting layer.

According to an embodiment of the present application, the first electrode may be disposed in a through hole of the second insulation layer.

According to a second aspect of the embodiments of the present application, a manufacturing method of a semiconductor integrated circuit device is provided, which includes: forming a first electrode on a substrate; forming a first insulation layer above the first electrode; etching a part including the first insulation layer to form a protruding block; depositing a resistance layer material above the protruding block to form a layer of thin film covering the protruding block; and forming a second electrode above the resistance layer, and enabling the second electrode to form full coverage for the resistance layer.

According to an embodiment of the present application, the manufacturing method may further include: forming an oxygen getting layer between the first electrode and the resistance layer, or between the second electrode and the resistance layer.

According to an embodiment of the present application, the manufacturing method may further include: forming an oxygen blocking layer between the first insulation layer and the oxygen getting layer.

According to an embodiment of the present application, the forming the first electrode on the substrate may include: depositing an insulation material on the substrate to form a second insulation layer; grooving in the second insulation layer to form a through hole; and depositing an electrode material in the through hole to form the first electrode.

According to an embodiment of the present application, before forming the resistance layer, the manufacturing method may further include: chamfering the protruding block.

According to an embodiment of the present application, after forming the second electrode above the resistance layer, the manufacturing method may further include: etching a part including the second electrode to form a storage cell matrix.

According to the semiconductor integrated circuit device and the manufacturing method therefor in the embodiments of the present application, the semiconductor integrated circuit device includes the resistance layer, the first electrode and the second electrode which are respectively disposed at two sides of the resistance layer; where the resistance layer is a layer of thin film covering the protruding block, the first electrode is a part of the protruding block or is connected with the lower end of the protruding block, the second electrode is disposed above the resistance layer, and forms full coverage for the resistance layer, and the first electrode and the second electrode are enabled to form the conductive filament on the side wall of the resistance layer in the manner of arranging the first insulation layer above the first electrode. The resistance layer covers the protruding block, and the conductive filament is formed on the side wall of the resistance layer, therefore, the area of the resistance region can be increased exponentially through increasing the height of the protruding block. In addition, since the second electrode forms the full coverage for the resistance layer, the area of the resistance region can be further maximized, so that a forming voltage (FV) of the conductive filament and a plasma induced damage (PID) effect are greatly reduced, and then the energy consumption is reduced, the performance is improved, and the life is prolonged.

It needs to be understood that, the implementation for the embodiments of the present application does not require realizing all of the beneficial effects above, but specific technical solutions can realize specific technical effects, and moreover, other implementation manners of the embodiments of the present application can further realize beneficial effects which are not mentioned above.

### BRIEF DESCRIPTION OF THE DRAWINGS

By reading the following detailed description with reference to the accompanying drawings, the above and other objectives, features and advantages of the exemplary embodiments of the present application will become easier to understand. In the drawings, several embodiments of the present application are shown in an exemplary and non-limiting manner.

In the drawings, the same or corresponding reference numerals denote the same or corresponding parts.

FIG. 1 is a schematic diagram of a change trend between a forming voltage of a conductive filament and an area of a resistance region, which is found by the inventor of the present application.

FIG. 2 is a schematic diagram of a section structure in an embodiment of a semiconductor integrated circuit device of the present application.

FIG. 3 is a schematic diagram of a section structure in another embodiment of a semiconductor integrated circuit device of the present application.

FIG. 4 is a schematic diagram of a section structure in another embodiment of a semiconductor integrated circuit device of the present application.

FIG. 5 is a schematic diagram of a section structure in another embodiment of a semiconductor integrated circuit device of the present application.

FIGS. 6A and 6B show a cross-section structure in an embodiment of a semiconductor integrated circuit device of the present application.

FIG. 7 is a schematic flowchart of a manufacturing method of a semiconductor integrated circuit device of the present application.

FIG. 8 is a schematic diagram of a manufacturing process in the embodiment shown in FIG. 2 of the present application.

FIG. 9 is a schematic diagram of a section structure in a certain stage of the manufacturing process in the embodiment shown in FIG. 2 of the present application.

FIG. 10 is a schematic diagram of a section structure in a certain stage of the manufacturing process in the embodiment shown in FIG. 2 of the present application.

FIG. 11 is a schematic diagram of a section structure in a certain stage of the manufacturing process in the embodiment shown in FIG. 2 of the present application.

FIG. 12 is a schematic diagram of a section structure in a certain stage of the manufacturing process in the embodiment shown in FIG. 2 of the present application.

FIG. 13 is a schematic diagram of a section structure in a certain stage of the manufacturing process in the embodiment shown in FIG. 2 of the present application.

FIG. 14 is a schematic diagram of a section structure in a certain stage of the manufacturing process in the embodiment shown in FIG. 2 of the present application.

FIG. 15 is a schematic diagram of a section structure in a certain stage of the manufacturing process in the embodiment shown in FIG. 2 of the present application.

FIG. 16 is a schematic diagram of a cross-section structure in a certain stage of the manufacturing process in the embodiment shown in FIG. 2 of the present application.

FIG. 17 is a schematic diagram of a manufacturing process in the embodiment shown in FIG. 3 of the present application.

FIG. 18 is a schematic diagram of a section structure in a certain stage of the manufacturing process in the embodiment shown in FIG. 3 of the present application.

FIG. 19 is a schematic diagram of a section structure in a certain stage of the manufacturing process in the embodiment shown in FIG. 3 of the present application.

FIG. 20 is a schematic diagram of a manufacturing process in the embodiment shown in FIG. 4 of the present application.

FIG. 21 is a schematic diagram of a section structure in a certain stage of the manufacturing process in the embodiment shown in FIG. 4 of the present application.

FIG. 22 is a schematic diagram of a section structure in a certain stage of the manufacturing process in the embodiment shown in FIG. 4 of the present application.

FIG. 23 is a schematic diagram of a section structure in a certain stage of the manufacturing process in the embodiment shown in FIG. 4 of the present application.

FIG. 24 is a schematic diagram of a manufacturing process in the embodiment shown in FIG. 5 of the present application.

FIG. 25 is a schematic diagram of a section structure in a certain stage of the manufacturing process in the embodiment shown in FIG. 5 of the present application.

FIG. 26 is a schematic diagram of a section structure in a certain stage of the manufacturing process in the embodiment shown in FIG. 5 of the present application.

FIG. 27 is a schematic diagram of a section structure in a certain stage of the manufacturing process in the embodiment shown in FIG. 5 of the present application.

FIG. 28 is a schematic diagram of a section structure in a certain stage of the manufacturing process in the embodiment shown in FIG. 5 of the present application.

### DETAILED DESCRIPTION OF THE EMBODIMENTS

In order to make the objectives, features, and advantages of the present application more apparent and easier to understand, the technical solutions in the embodiments of the present application will be clearly and completely described below with reference to the accompanying drawings in the embodiments of the present application. Apparently, the embodiments described are merely a part rather than all of the embodiments of the present application. On the basis of the embodiments in the present application, all other embodiments obtained by those skilled in the art without creative efforts shall fall within the protection scope of the present application.

In the description for the present specification, the descriptions for the terms “an embodiment”, “some embodiments”, “an example”, “specific example”, or “some examples”, etc. mean that specific features, structures, materials, or characteristics described in conjunction with the embodiments or examples are included in at least two embodiments or examples of the present application. Moreover, the specific features, structures, materials, or characteristics described can be combined in any one or more embodiments or examples in an appropriate manner. In addition, in the case of no mutual contradiction, those skilled in the art can combine and compose the different embodiments or examples described in the present specification and the features of the different embodiments or examples.

In addition, the terms “first” and “second” are merely used for a description purpose, and cannot be interpreted as indicating or implying relative importance or implicitly indicating the number of the technical features indicated. Therefore, the features defined with “first” and “second” can explicitly or implicitly include at least two features. In the description of the present application, “a plurality of” means two or more than two, unless otherwise specified.

In order to better meet the demand of miniaturization and guarantee the performance of the components, the inventor of the present application has carried out a series of experiments for continuously narrowing the resistance region in the RRAM, and observed and recorded the different performance of various performance indicators of the RRAM under changes in the size of the resistance region, so as to research the degree of influence of the changes in the size of the resistance region on the performance indicators.

FIG. 1 shows a change trend of a forming voltage of a conductive filament along with a size of a resistance region, which is recorded by the inventor of the present application in an experiment process. The horizontal axis represents the size of the resistance region, and the longitudinal axis represents the value of the forming voltage of the conductive filament.

Through the data shown in FIG. 1, the inventor of the present application found that: the smaller the resistance region, the higher the forming voltage of the conductive filament, which is required to form the conductive filament; and the larger the resistance region, the lower the forming voltage of the conductive filament, which is required to form the conductive filament.

In addition, the inventor of the present application further found that: the smaller the resistance region, the greater a plasma induced damage effect; and the larger the resistance region, the lower the plasma induced damage effect.

Therefore, the inventor of the present application creatively came up with the idea that, if it is possible to enlarge the resistance region in a unit space, the forming voltage of the conductive filament, and the plasma induced damage effect can be further reduced, so that the demand of miniaturization is better met.

On the basis of the above invention concept, the present application provides a semiconductor integrated circuit device and a manufacturing method therefor.

In order to describe a three-dimensional structure of the semiconductor integrated circuit device from a plurality of perspectives, in the present application, a schematic diagram of a structure obtained through vertically cutting the semiconductor integrated circuit device is called a schematic diagram of a section structure; and a schematic diagram of a structure obtained through horizontally cutting the semiconductor integrated circuit device is called a schematic diagram of a cross-section structure.

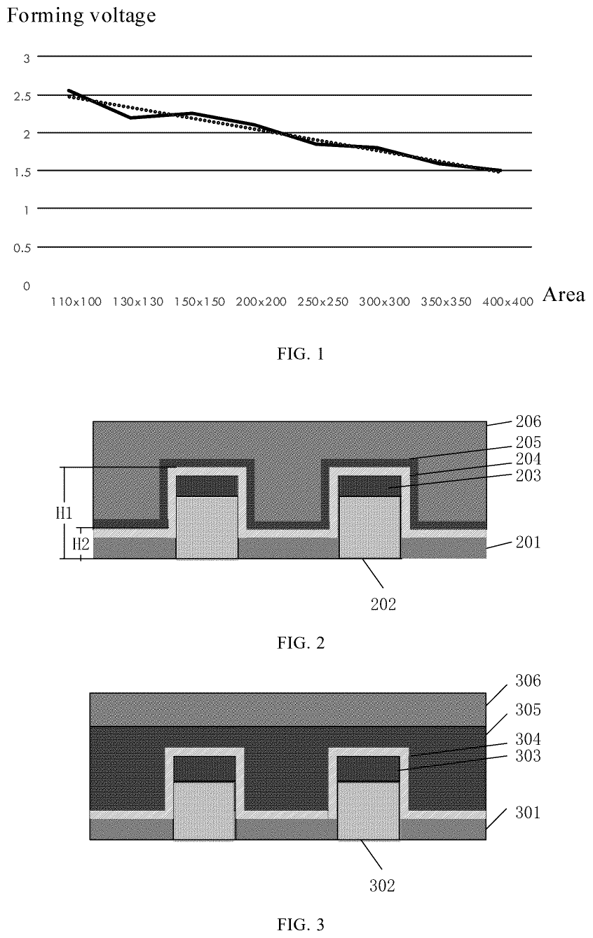

FIG. 2 is a schematic diagram of a section structure in an embodiment of a semiconductor integrated circuit device of the present application.

As shown in FIG. 2, the semiconductor integrated circuit device includes a resistance layer 204, a first electrode 202 and a second electrode 206 which are respectively disposed at two sides of the resistance layer, where the resistance layer 204 is a layer of thin film covering a protruding block, and includes a top with a first height H1, a bottom with a second height H2, and a side wall connecting the top with the bottom, and the second height H2 is smaller than the first height H1. The first electrode 202 is a part of the protruding block; the second electrode 206 is disposed above the resistance layer 204, and forms full coverage for the resistance layer 204; and the semiconductor integrated circuit device further includes a first insulation layer 203, and the first insulation layer 203 is disposed above the first electrode 202, so that the first electrode 202 and the second electrode 206 form a conductive filament on the side wall of the resistance layer 204.

The first electrode 202 of the semiconductor integrated circuit device is disposed above a substrate, and protrudes upwards to form the protruding block together with the first insulation layer 203 stacked above the first electrode 202. The resistance layer 204 covers a surface of a protruding part (including an upper surface and a side surface of the first insulation layer 203, a part of a side surface of the first electrode 202) of the protruding block in the form of the thin film.

The first insulation layer 203 is disposed below the resistance layer 204 and above the first electrode 202, and a partition can be formed in a horizontal direction between the first electrode 202 and the second electrode 206, so that the first electrode 202 and the second electrode 206 are prevented from forming the conductive filament at the top of the resistance layer 204. In this way, after the first electrode 202 and the second electrode 206 are powered on, the conductive filament can be formed on the side wall of the resistance layer 204, so that a resistance region is disposed in the side wall of the resistance layer 204.

The resistance region disposed in the side wall of the resistance layer 204 is formed through deposition and is not etched, so that there is no damage caused by etching; and moreover, since the resistance region is disposed in the side wall of the resistance layer 204, the problem of unevenness caused by depression of interconnection via of metal layers can also be avoided, therefore, better performance and longer life of the resistance layer can be achieved.

The resistance layer 204 can be prepared from one or more resistance materials. The common resistance materials include: transition metal oxides (TMOs) such as aluminum oxide (AlₓO_{y}), copper oxide (CuₓO_{y}), hafnium oxide (HfₓO_{y}) and the like.

The first electrode 202 and the second electrode 206 can be prepared from one or more electrode materials. The common electrode materials include aluminum (Al), copper (Cu), gold (Au), platinum (Pt), tantalum (Ta), tantalum nitride (TaN), titanium (Ti), titanium nitride (TiN), tungsten (W), tungsten nitride (WN), and the like.

The first insulation material 203 can be prepared from one or more insulation materials. The common insulation materials include nitrides, oxides, and the like.

In embodiments of the present application, the resistance layer 204 covers the protruding block to form the thin film, the resistance region is formed in the side wall of the resistance layer 204, and the size of the resistance region is in direct proportion to the cross-section circumference and the height of the protruding block.

Therefore, the resistance region in a unit space can be enlarged only through increasing the cross-section area and the height of the protruding block in the unit space, so that the forming voltage of the conductive filament and the plasma induced damage effect can be greatly reduced.

In addition, as shown in FIG. 2, the semiconductor integrated circuit device in the embodiment of the present application may further include a plurality of first electrodes 202, and a plurality of protruding blocks are formed, so that the resistance layer 204 covering the protruding blocks forms a rectangular waveform in the schematic diagram of the section structure.

When the resistance layer 204 covers the plurality of protruding blocks, the height of each protruding block can be further reduced in the case of keeping the area of the resistance region unchanged, so that formation for voids in the deposition process, or generation for a bridging effect in the case of power-on are avoided.

Furthermore, the embodiment of the present application shown in FIG. 2 further includes a second insulation layer 201, and an oxygen getting layer 205 is additionally arranged.

The second insulation layer 201 is a common structure disposed above the substrate, and configured to isolate components, so as to avoid short circuit after power-on.

The oxygen getting layer 205 covers above the resistance layer 204 in the form of a thin film, disposed between the second electrode 206 and the resistance layer 204, and configured to attract more oxygen, so as to make the formation for the conductive filament more stable. Common oxygen getting layer materials include: titanium (Ti), tantalum (Ta), and the like.

It should be noted that, the oxygen getting layer 205 is a gain structure for making the performance of a storage unit better, and is not a necessary structure for the storage unit, and the implementer can choose to arrange or not arrange the oxygen getting layer 205 as needed.

In this way, through enabling the resistance layer 204 to cover the plurality of protruding blocks to form a rectangular wave structure, and additionally arranging the oxygen getting layer 205, the embodiment of the present application shown in FIG. 2 can not only better meet the demand of miniaturization, but also further improve the quality, performance and the life of the semiconductor integrated circuit device.

FIG. 3 is a schematic diagram of a section structure in another embodiment of a semiconductor integrated circuit device of the present application.

As shown in FIG. 3, the semiconductor integrated circuit device includes: a resistance layer 304, a first electrode 302 and a second electrode 306 which are respectively disposed at two sides of the resistance layer, where the resistance layer 304 is a layer of thin film covering a protruding block, and includes a top with a first height, a bottom with a second height, and a side wall connecting the top with the bottom, and the second height is smaller than the first height. The first electrode 302 is a part of the protruding block; the second electrode 306 is disposed above the resistance layer 304, and forms full coverage for the resistance layer 304; and the semiconductor integrated circuit device further includes a first insulation layer 303, and the first insulation layer 303 is disposed above the first electrode 302, so that the first electrode 302 and the second electrode 306 form a conductive filament on the side wall of the resistance layer 304.

In addition, the embodiment of the present application shown in FIG. 3 further includes a second insulation layer 301 and an oxygen getting layer 305. The oxygen getting layer 305 is a structure obtained through depositing an oxygen getting layer material to fully fill a groove, and then grinding the oxygen getting layer material to be flat. After that, an electrode material is deposited above the oxygen getting layer 305 to form the second electrode 306 with/in a planar structure.

Since the volume of the oxygen getting layer in the embodiment of the present application shown in FIG. 3 is larger, more oxygen can be attracted, which is conducive to further reducing the forming voltage of the conductive filament.

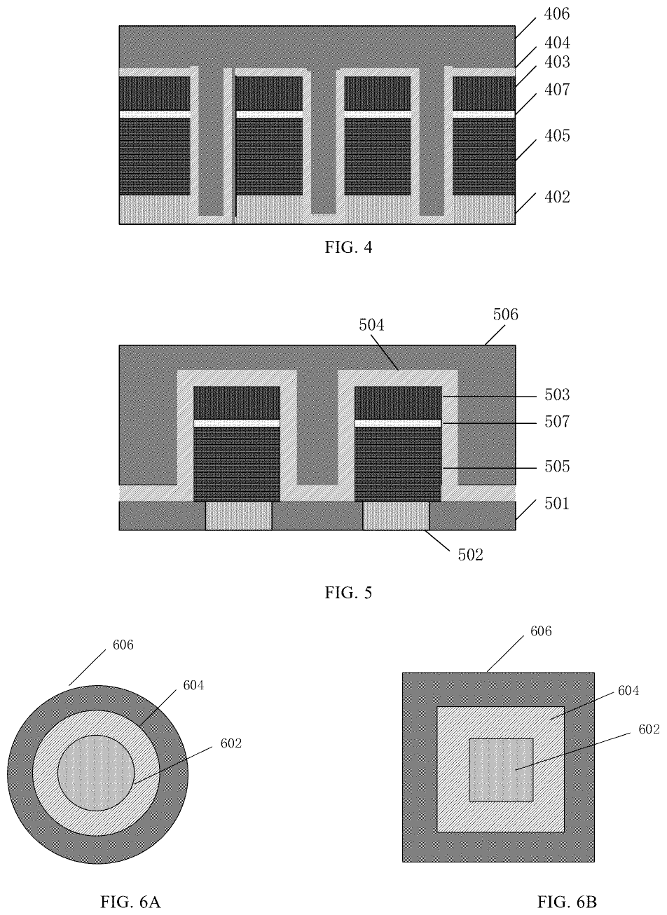

FIG. 4 is a schematic diagram of a section structure in another embodiment of a semiconductor integrated circuit device of the present application.

As shown in FIG. 4, the semiconductor integrated circuit device includes: a resistance layer 404, a first electrode 402 and a second electrode 406 which are respectively disposed at two sides of the resistance layer, where the resistance layer 404 is a layer of thin film covering a protruding block, and includes a top with a first height, a bottom with a second height, and a side wall connecting the top with the bottom, and the second height is smaller than the first height. The first electrode 402 is a part of the protruding block; the second electrode 406 is disposed above the resistance layer 404, and forms full coverage for the resistance layer 404; and the semiconductor integrated circuit device further includes a first insulation layer 403, and the first insulation layer 403 is disposed above the first electrode 402, so that the first electrode 402 and the second electrode 406 form a conductive filament on the side wall of the resistance layer 404.

In the embodiment of the present application shown in FIG. 4, an oxygen getting layer 405 is disposed above the first electrode 402, and an oxygen blocking layer 407 is further additionally arranged between the oxygen getting layer 405 and the first insulation layer 403.

The oxygen blocking layer 407 is mainly configured to block the oxygen getting layer from getting oxygen atoms of the first insulation layer 403, so that the formation for the conductive filament is more stable. The oxygen blocking layer 407 is a gain structure for making the performance of a storage unit better, and is not a necessary structure for the storage unit, and the implementer can choose to arrange or not arrange the oxygen blocking layer 407 as needed.

Materials such as titanium nitride (TiN), tantalum nitride (TaN), aluminum oxide (AlₓO_{y}) and the like can be adopted for the oxygen blocking layer 407.

FIG. 5 is a schematic diagram of a section structure in another embodiment of a semiconductor integrated circuit device of the present application.

As shown in FIG. 5, the semiconductor integrated circuit device includes: a resistance layer 504, a first electrode 502 and a second electrode 506 which are respectively disposed at two sides of the resistance layer, where the resistance layer 504 is a layer of thin film covering a protruding block, and includes a top with a first height, a bottom with a second height, and a side wall connecting the top with the bottom, and the second height is smaller than the first height. The first electrode 502 is connected with a lower end of the protruding block; the second electrode 506 is disposed above the resistance layer 504, and forms full coverage for the resistance layer 504; and the semiconductor integrated circuit device further includes a first insulation layer 503, and the first insulation layer 503 is disposed above the first electrode 502, so that the first electrode 502 and the second electrode 506 form a conductive filament on the side wall of the resistance layer 504.

In addition, in the embodiment of the present application shown in FIG. 5, a second insulation layer 501 and an oxygen getting layer 505 are further included.

In the embodiment of the present application shown in FIG. 5, the first electrode 502 is disposed in a through hole of the second insulation layer 501. In this way, the height of the whole semiconductor integrated circuit device can be further reduced, so that the demand of miniaturization is better met.

FIGS. 6A and 6B show a cross-section structure of a storage unit in an embodiment of the present application. As shown in FIGS. 6A and 6B, in an embodiment of the present application, the first electrode 602 can be a cylinder with a cross section which is circular or elliptical, and as shown in the cross section FIG. 6A at the left side, a circular ring formed by the resistance layer 604 and the second electrode 606 surrounds an outer side of the first electrode 602. In another embodiment of the present application, the first electrode 602 can also be a cube with a horizontal cross section which is a square or rectangular, and as shown in the cross section FIG. 6B at the right side, a square ring formed by horizontal cross sections of the resistance layer 604 and the second electrode 606 surrounds the outer side of the first electrode 602. Theoretically, the cross section of the first electrode 602 can be in any suitable shape.

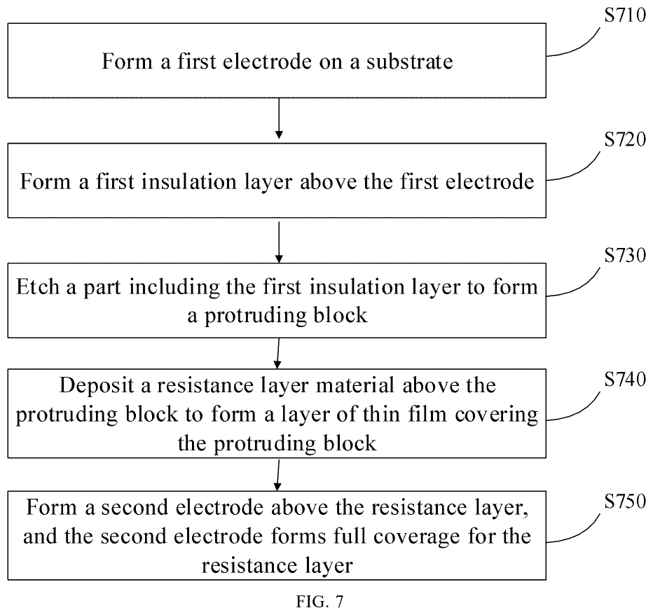

Furthermore, the present application further provides a manufacturing method of a semiconductor integrated circuit device. As shown in FIG. 7, the manufacturing method includes:
operation S710, forming a first electrode on a substrate;
in the present application, the substrate is a generalized substrate, refers to a structure before preparation for a storage unit, and usually includes a circuit capable of being connected with the first electrode, and the like.

The following method can be adopted for forming the first electrode on the substrate:
depositing an insulation material to form a second insulation layer;
depositing an electrode material, and then etching to form the first electrode,
or,
carving a hole in the second insulation layer to form a through hole, and depositing an electrode material in the through hole to form the first electrode;
or
adopting any other applicable method.

Any applicable electrode materials can be used as the electrode material.

Any applicable etching processes can be used as the etching process, such as dry etching or wet etching.

Any applicable deposition processes can also be used as the deposition process, such as a physical vapor deposition method, a chemical vapor deposition method, or an atomic layer deposition method.

Operation S720, forming a first insulation layer above the first electrode;
the formation for the first insulation layer above the first electrode can usually be realized through depositing an insulation material on the first electrode.

Any applicable electrode materials can be used as the insulation material, and any applicable deposition processes can also be used as the deposition process.

Operation S730, etching a part including the first insulation layer to form a protruding block;
herein, the etching is mainly performed on the part including the first insulation layer until a position where the part is level with the second insulation layer is reached.

For the embodiment of the present application, in which the first electrode is disposed above the second insulation layer, the first insulation layer and the first electrode can be etched to form the protruding block; and
for the embodiment of the present application, in which the first electrode is disposed in a through hole of the second insulation layer, the protruding first insulation layer and other dielectric layers (such as an oxygen getting layer, an oxygen blocking layer and the like) can be etched to form the protruding block.

Any applicable etching processes can be used for the etching.

Operation S740, depositing a resistance layer material above the protruding block to form a layer of thin film covering the protruding block;
it should be noted that, when the resistance layer material is deposited in the operation S740, the resistance layer material covers above the protruding block to form the thin film instead of filling a groove to be flat, so that the original protruding block structure is reserved, and then a conductive filament is formed on a side wall.

The resistance layer material can be any applicable resistance layer materials, and any applicable deposition processes can be used as the deposition process.

Operation S750, forming a second electrode above the resistance layer, so that the second electrode forms full coverage for the resistance layer.

The second electrode is usually formed through depositing a second electrode material above the resistance layer.

Any applicable electrode materials can be used as the electrode material, and any applicable deposition process can also be used as the deposition process.

It should be noted that, the above steps are merely the steps necessary for manufacturing the semiconductor integrated circuit device in the embodiment of the present application, rather than all of the steps. In the process of manufacturing the semiconductor integrated circuit device, steps such as depositing an oxygen blocking layer, depositing an oxygen getting layer, and forming other structures can also be added according to a product design for the semiconductor integrated circuit device. Any applicable deposition processes can be selected as the deposition process according to a specific implementation condition.

According to an embodiment of the present application, the manufacturing method further includes: forming an oxygen getting layer between the first electrode and the resistance layer, or between the second electrode and the resistance layer.

According to an embodiment of the present application, the manufacturing method further includes: forming an oxygen blocking layer between the first insulation layer and the oxygen getting layer.

According to an embodiment of the present application, the forming the first electrode on the substrate includes: depositing an insulation material above/on the substrate to form a second insulation layer; grooving in the second insulation layer to form a through hole; and depositing an electrode material in the through hole to form the first electrode.

According to an embodiment of the present application, before forming the resistance layer, the manufacturing method further includes: chamfering the protruding block.

According to an embodiment of the present application, after forming the second electrode above the resistance layer, the manufacturing method further includes: etching a part including the second electrode to form a storage cell matrix.

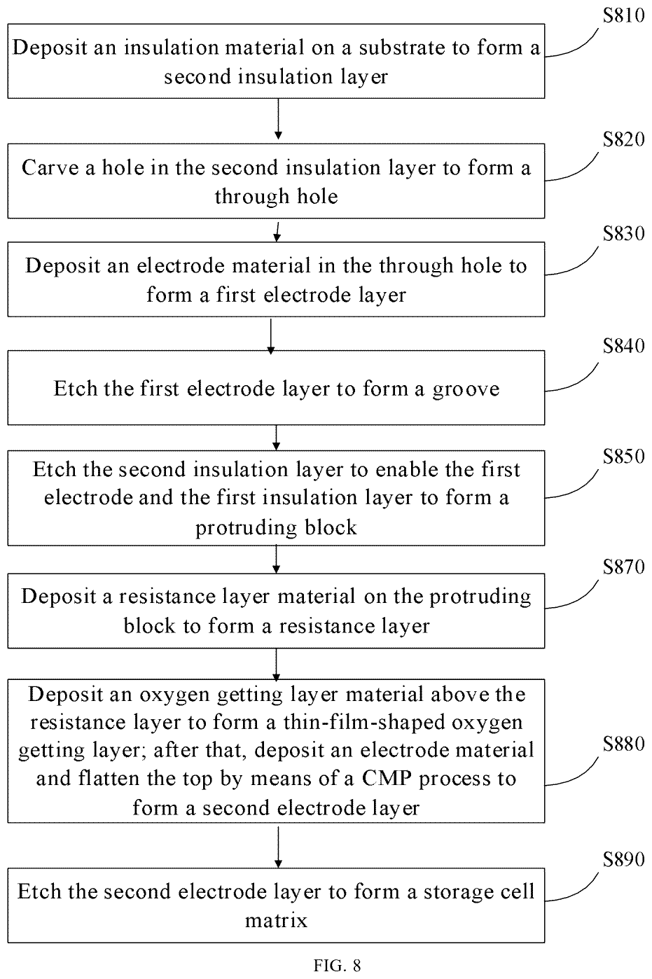

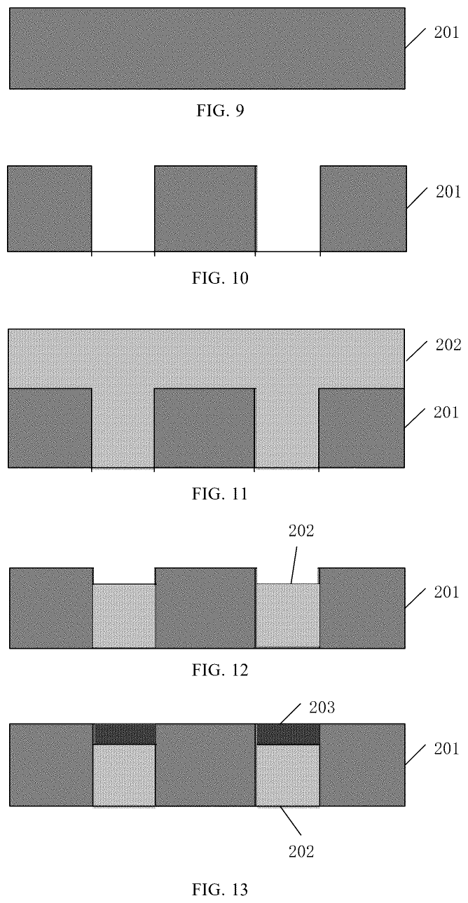

FIG. 8 shows a main process of manufacturing the semiconductor integrated circuit device shown in FIG. 2, which includes:
step S810, depositing an insulation material on a substrate to form a second insulation layer 201, so as to obtain a structure shown in FIG. 9;
in the embodiment of the present application, an oxide is used as the insulation material, and the implementer can also use other insulation materials for forming the second insulation layer 201 according to specific implementation demands and implementation conditions.

Step S820, carving a hole in the second insulation layer 201 to form a through hole, so as to obtain a structure shown in FIG. 10;
step S830, depositing an electrode material in the through hole to form a first electrode layer 202, so as to obtain a structure shown in FIG. 11; and
in the embodiment of the present application, a chemical vapor deposition method is used, and the implementer can also use other deposition processes according to specific implementation demands and implementation conditions.

Step S840, etching the first electrode layer 202 to form a groove, so as to obtain a structure shown in FIG. 12;
the etching process in the embodiment of the present application is dry etching.

In some other embodiments, a chemical mechanical polishing (CMP) process can also be adopted to form a groove.

Step S850, depositing an insulation material in the groove to form a first insulation layer 203, so as to obtain a structure shown in FIG. 13;
in the embodiment of the present application, a nitride is used as the insulation material for forming the first insulation layer 203, and the implementer can also use other insulation materials for forming the first insulation layer 203 according to specific implementation demands and implementation conditions.

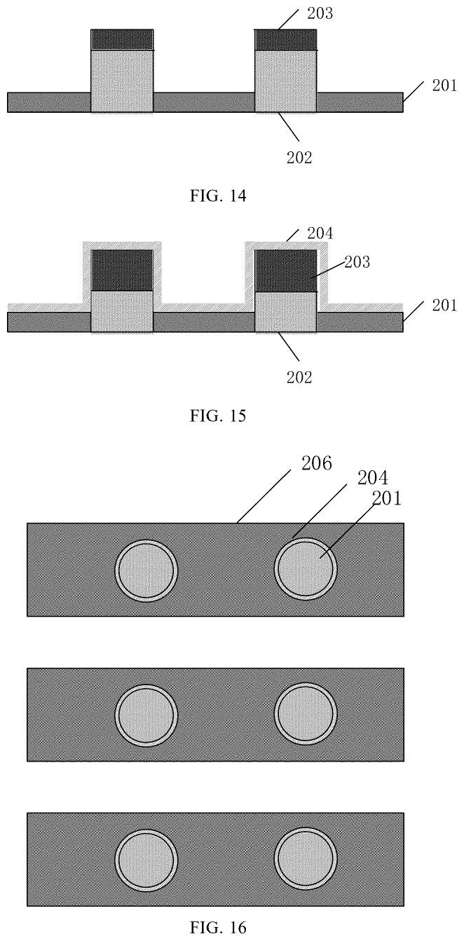

Step S860, etching the second insulation layer 201 to enable the first electrode 202 and the first insulation layer 203 to form a protruding block, so as to obtain a structure shown in FIG. 14;
step S870, depositing a resistance layer material on the protruding block to form a resistance layer 204, so as to obtain s structure shown in FIG. 15;
where an atomic layer deposition method can be used when the resistance layer material is deposited, and transition metal oxides (TMOs) such as aluminum oxide (AlₓO_{y}), copper oxide (CuₓO_{y}), hafnium oxide (HfₓO_{y}) and the like can be used as the resistance layer material.

Step S880, depositing an oxygen getting layer material above the resistance layer 204 to form a thin-film-shaped oxygen getting layer 205; after that, depositing an electrode material and flattening the top by means of a chemical mechanical polishing process to form a second electrode layer 206, so as to obtain a structure shown in FIG. 2; and step S890, etching the second electrode layer 206 to form a storage cell matrix shown in FIG. 16, so as to obtain the semiconductor integrated circuit device in the embodiment of the present application shown in FIG. 2.

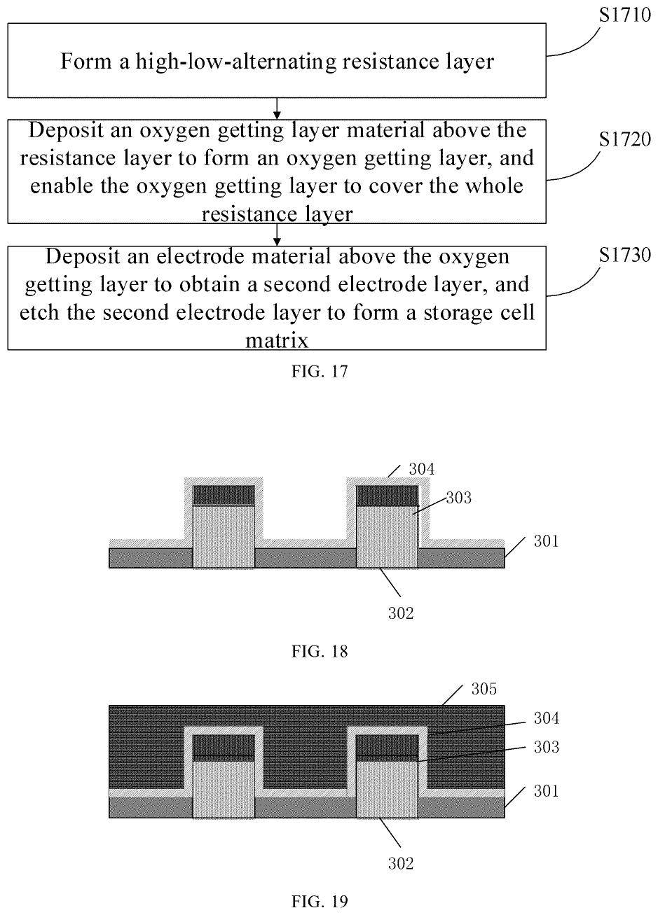

FIG. 17 shows a main process of manufacturing the semiconductor integrated circuit device shown in FIG. 3, which includes:
step S1710, forming a high-low-alternating resistance layer 304, so as to obtain a structure shown in FIG. 18; and
the description for the operation S810 to the operation S870 of the manufacturing method in the embodiment of the present application shown in FIG. 8 can be referred to for specific steps, and the specific steps will not be repeated herein.

Step S1720, depositing an oxygen getting layer material above the resistance layer 304 and flattening the top by means of a chemical mechanical polishing process to form an oxygen getting layer 305, and enabling the oxygen getting layer 305 to cover the whole resistance layer 304, so as to obtain a structure shown in FIG. 19; and
step S1730, depositing an electrode material above the oxygen getting layer 305 to obtain a second electrode layer 306, and etching the second electrode layer 306 to form a storage cell matrix, so as to obtain the semiconductor integrated circuit device in the embodiment of the present application shown in FIG. 3.

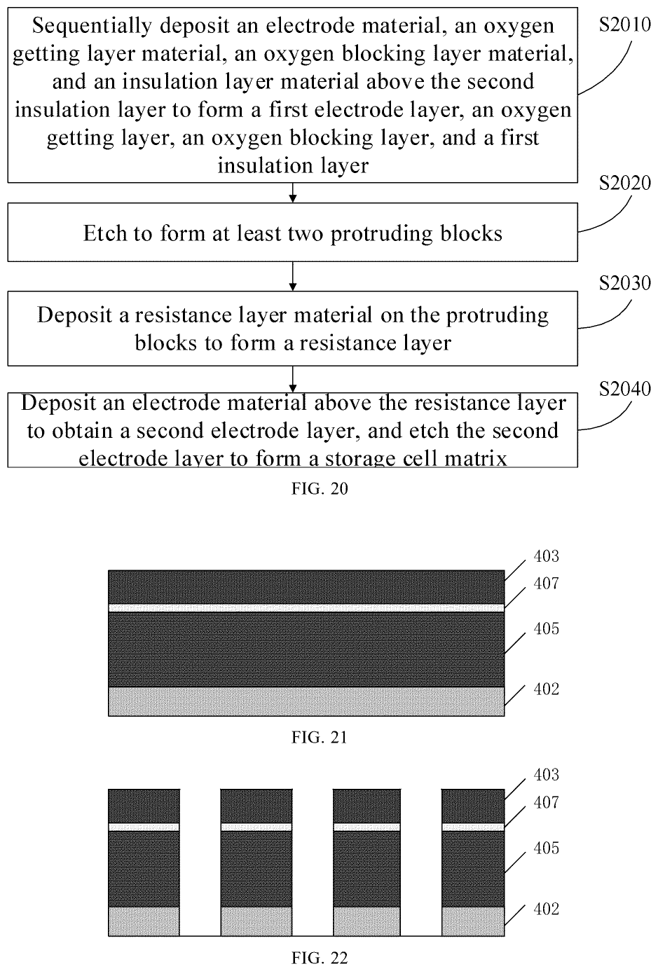

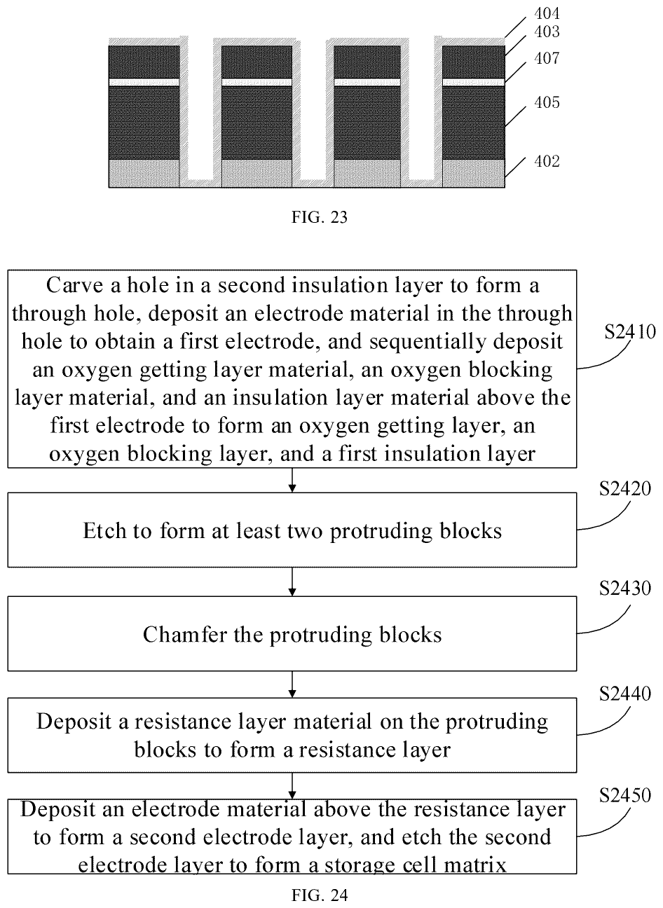

FIG. 20 shows a main process of manufacturing the semiconductor integrated circuit device shown in FIG. 4, which includes:
step S2010, sequentially depositing an electrode material, an oxygen getting layer material, an oxygen blocking layer material, and an insulation layer material above a second insulation layer to form a first electrode layer 402, an oxygen getting layer 405, an oxygen blocking layer 407, and a first insulation layer 403, so as to obtain a structure shown in FIG. 21;
step S2020, etching to enable the first electrode layer 402, the oxygen getting layer 405, the oxygen blocking layer 407, and the first insulation layer 403 to form at least two protruding blocks, so as to obtain a structure shown in FIG. 22;
step S2030, depositing a resistance layer material on the protruding blocks to form a resistance layer 404, so as to obtain s structure shown in FIG. 23; and
step S2040, depositing an electrode material above the resistance layer 404 to form a second electrode layer 406, and etching the second electrode layer 406 to form a storage cell matrix, so as to obtain the semiconductor integrated circuit device in the embodiment of the present application shown in FIG. 4.

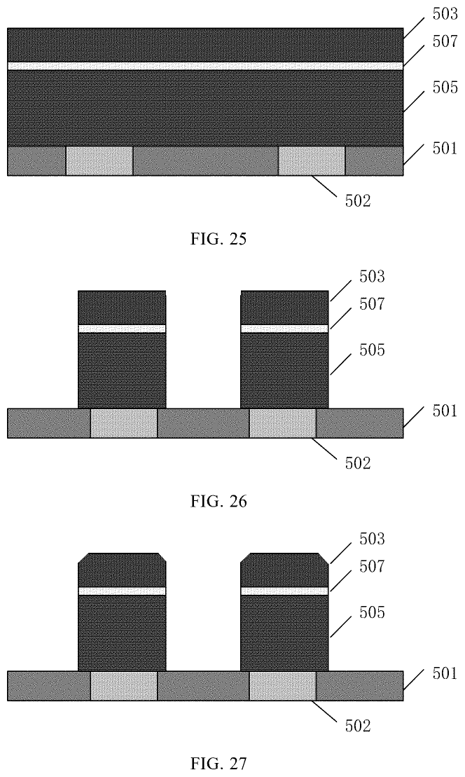

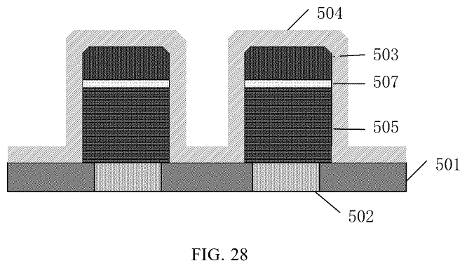

FIG. 24 shows a main process of manufacturing the semiconductor integrated circuit device shown in FIG. 5, which includes:
Step S2410, carving a hole in a second insulation layer 501 to form a through hole, depositing an electrode material in the through hole to obtain a first electrode 502, and sequentially depositing an oxygen getting layer material, an oxygen blocking layer material, and an insulation layer material above the first electrode 502 to form an oxygen getting layer 505, an oxygen blocking layer 507, and a first insulation layer 503, so as to obtain a structure shown in FIG. 25;
step S2420, etching to enable the oxygen getting layer 505, the oxygen blocking layer 507, and the first insulation layer 503 to form at least two protruding blocks, so as to obtain a structure shown in FIG. 26; and
step S2430, chamfering the protruding blocks to obtain a structure shown in FIG. 27;
where the chamfering refers to chamfering off a convex-corner part of the first insulation layer 503 to improve the gap filling capability, so that the subsequent steps of depositing a resistance layer material and a second electrode are easier, and the manufactured semiconductor integrated circuit device is higher in quality.
step S2440, depositing a resistance layer material on the protruding blocks to form a resistance layer 504, so as to obtain s structure shown in FIG. 28; and
step S2450, depositing an electrode material above the resistance layer 504 to form a second electrode layer 506, and etching the second electrode layer 506 to obtain the semiconductor integrated circuit device in the embodiment of the present application shown in FIG. 5.

It should be noted that the embodiments of the present application shown in FIG. 2 to FIG. 28 are merely exemplary descriptions, and do not limit the implementation manners of the semiconductor integrated circuit device and the manufacturing method therefor in the present application, and the implementer can further refine and extend on the basis of the above embodiments to obtain more embodiments.

It should be noted that, the terms “including,” “containing,” or any other variations thereof herein are intended to encompass non-exclusive inclusions, so that a process, a method, an article, or an apparatus that includes a series of elements not only includes those elements, but also includes other elements which are not explicitly listed, or also includes inherent elements of the process, the method, the article, or the apparatus. In the absence of more limitations, the element defined by the statement “including a . . . ” does not exclude the existence of other identical elements in the process, the method, the article, or the device that includes that element.

In the several embodiments provided by the present application, it should be understood that, the disclosed device and method can also be realized in other manners. The device embodiments described above are merely schematic, for embodiment, the division of units is merely a logical function division, and there can be other division manners in actual realization, for embodiment: a plurality of units or assemblies can be combined, or can be integrated into another apparatus, or some features can be ignored or not executed. In addition, the coupling, or direct coupling, or communication connection among the components displayed or discussed can be indirect coupling or communication connection through some interfaces, devices, or units, and can be electrical, mechanical, or in other forms.

The above merely describes the specific implementation manners of the present application, but the protection scope of the present application is not limited thereto, and any person skilled in the art can easily conceive variations or substitutions within the technical scope disclosed by the present application, and these variations or substitutions shall all fall within the protection scope of the present application. Therefore, the protection scope of the present application should be subject to the protection scope of the claims.

What is claimed is:

1. A semiconductor integrated circuit device, comprising a resistance layer, a first electrode and a second electrode, wherein the first electrode and the second electrode are respectively disposed at two sides of the resistance layer, wherein:
the resistance layer is a layer of thin film covering a protruding block, and comprises a top with a first height, a bottom with a second height, and a side wall connecting the top with the bottom, and the second height is smaller than the first height;
the first electrode is a part of the protruding block or is connected with a lower end of the protruding block;
the second electrode is disposed above the resistance layer, and forms full coverage for the resistance layer; and
the semiconductor integrated circuit device further comprises a first insulation layer, and the first insulation layer is disposed above the first electrode, wherein the first electrode and the second electrode form a conductive filament on the side wall of the resistance layer.

2. The semiconductor integrated circuit device according to claim 1, further comprising:
an oxygen getting layer disposed between the first electrode and the resistance layer, or disposed between the second electrode and the resistance layer.

3. The semiconductor integrated circuit device according to claim 2, further comprising:
an oxygen blocking layer disposed between the first insulation layer and the oxygen getting layer.

4. The semiconductor integrated circuit device according to claim 2, wherein the first electrode is disposed in a through hole of a second insulation layer.

5. A manufacturing method of a semiconductor integrated circuit device, comprising:
forming a first electrode on a substrate;
forming a first insulation layer above the first electrode;
etching a part comprising the first insulation layer to form a protruding block;
depositing a resistance layer material above the protruding block to form a layer of thin film covering the protruding block; and
forming a second electrode above a resistance layer, and enabling the second electrode to form full coverage for the resistance layer.

6. The manufacturing method according to claim 5, further comprising:
forming an oxygen getting layer between the first electrode and the resistance layer, or between the second electrode and the resistance layer.

7. The manufacturing method according to claim 6, further comprising:
forming an oxygen blocking layer between the first insulation layer and the oxygen getting layer.

8. The manufacturing method according to claim 5, wherein the step of forming the first electrode on the substrate comprises:
depositing an insulation material on the substrate to form a second insulation layer;
grooving in the second insulation layer to form a through hole; and
depositing an electrode material in the through hole to form the first electrode.

9. The manufacturing method according to claim 5, further comprising: before forming the resistance layer,
chamfering the protruding block.

10. The manufacturing method according to claim 5, further comprising: after forming the second electrode above the resistance layer,
etching a part comprising the second electrode to form a storage cell matrix.
